(19) United States
(12) Patent Application Publication
(10) Pub. No.: US 2026/0045963 A1
(43) Pub. Date: Feb. 12, 2026

(54) NOISE-CANCELING LOW NOISE AMPLIFIER (LNA) CIRCUIT

(71) Applicant: Qorvo US, Inc., Greensboro, NC (US)

(72) Inventors: Baker Scott, San Jose, CA (US); Marcus Granger-Jones, Scotts Valley, CA (US); George Maxim, Saratoga, CA (US)

(21) Appl. No.: 19/289,534

(22) Filed: Aug. 4, 2025

Related U.S. Application Data
(60) Provisional application No. 63/680,119, filed on Aug. 7, 2024.

(51) Int. Cl. H04B 1/12; H03F 3/19; H04B 1/40

(52) U.S. Cl. CPC H04B 1/123; H03F 3/19; H04B 1/40; H03F 2200/165; H03F 2200/294; H03F 2200/387; H03F 2200/451

(57) ABSTRACT

A noise-canceling low noise amplifier (LNA) is disclosed. In one aspect, an LNA path may include a plurality of inputs that are split into a main path (having a main LNA) and an inverting path. A multiplexer (MUX) in the inverting path generates switch noise which passes into both the switch path and the main path. The switch noise is inverted in the inverting path and also amplified. The switch noise is also amplified in the main path by the LNA. The inverted amplified switch noise and the amplified switch noise are then destructively summed to reduce or remove the switch noise at an output. The inverting path uses an active element in the form of an amplifier, which allows for substantial consolidation of matching circuits, thereby reducing size of the LNA path.

### PRIORITY APPLICATION

The present application claims priority to U.S. Provisional Patent Application Ser. No. 63/680,119, filed Aug. 7, 2024, and entitled “NOISE-CANCELING LOW NOISE AMPLIFIER (LNA) CIRCUIT,” which is incorporated herein by reference in its entirety

### BACKGROUND

### I. Field of the Disclosure The technology of the disclosure relates generally to low noise amplifiers (LNAs) in a wireless transceiver.

### II. Background

Communication devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to push more data to mobile communication devices. This pressure has resulted in more frequency bands in the electromagnetic spectrum being allocated for wireless communication. These disparate bands put pressure on the receivers to condition incoming signals for further processing. Accordingly, there is room for innovation in the receiver portions of wireless transceivers.

### SUMMARY

Aspects disclosed in the detailed description include a noise-canceling low noise amplifier (LNA) circuit. In particular, a low noise amplifier circuit may include a plurality of inputs that are split into a main path (having a main LNA) and an inverting path. A multiplexer (MUX) in the inverting path generates switch noise which passes into both the switch path and the main path. The switch noise is inverted in the inverting path and also amplified. The switch noise is also amplified in the main path by the LNA. The inverted amplified switch noise and the amplified switch noise are then destructively summed to reduce or remove the switch noise at an output. The inverting path uses an active element in the form of an amplifier, which allows for substantial consolidation of matching circuits, thereby reducing the size of the LNA circuit. Additionally, some portions of the LNA may be shared, further reducing the size of the LNA circuit.

In this regard, in one aspect, an LNA circuit is disclosed. The LNA circuit includes a plurality of receive paths, each comprising a respective input node, wherein each receive path splits into a main path and an inverting path and a switching circuit comprising a plurality of switches, each of the plurality of switches coupled to a respective receive path among the plurality of receive paths. The switching circuit is configured to couple one of the respective input nodes to the inverting path and introduce noise to the inverting path and the main path. Wherein the main path comprises an LNA configured to amplify the noise introduced by the switching circuit wherein the inverting path comprises an impedance matching circuit, and an inverting amplifier configured to amplify the noise introduced by the switching circuit. The LNA circuit also includes a summation node configured to sum destructively the noise in the main path and the inverting path.

In another aspect, a wireless communication device is disclosed. The wireless communication device includes a baseband processor (BBP) and a transceiver coupled to the BBP, the transceiver comprising a receiver, which comprises an LNA. The LNA includes a plurality of receive paths, each comprising a respective input node, wherein each receive path splits into a main path and an inverting path and a switching circuit comprising a plurality of switches, each of the plurality of switches coupled to a respective input node. The switching circuit is configured to couple one of the respective input nodes to the inverting path; and introduce noise to the inverting path and the main path. Wherein the main path comprises an LNA configured to amplify the noise introduced by the switching circuit, wherein the inverting path comprises an impedance matching circuit; and an inverting amplifier configured to amplify the noise introduced by the switching circuit. The LNA also includes a summation node configured to sum destructively the noise in the main path and the inverting path.

In another aspect, a method of canceling noise at a receiver is disclosed. The method includes splitting a received signal onto a main path and an inverting path and introducing noise on the main path and the inverting path with a switch in the inverting path. The method also includes using an active impedance matching amplifier in the inverting path to match impedance and amplify noise from the switch, amplifying the noise on the main path with an LNA, and destructively summing noise from the inverting path and the main path.

### BRIEF DESCRIPTION OF THE DRAWINGS

FIG. 1 is a block diagram of a conventional low noise amplifier (LNA) circuit with duplicated elements to accommodate different frequencies and/or inputs;

FIG. 2 is a block diagram of an LNA circuit having a main path and an inverting path according to aspects of the present disclosure;

FIG. 3A is a block diagram with details of one exemplary aspect of the inverting path of the LNA circuit of FIG. 2;

FIG. 3B is a block diagram with details of a second exemplary aspect of the inverting path of the LNA circuit of FIG. 2;

FIG. 4A is a block diagram with details of one exemplary way to sum the inverting path and the main path of the LNA circuit of FIG. 2;

FIG. 4B is a block diagram with details of a second exemplary way to sum the inverting path and the main path of the LNA circuit of FIG. 2;

FIG. 5A is a block diagram highlighting the relative position of the switches of the inverting path multiplexer relative to the split in the inverting path and the main path of the LNA circuit of FIG. 2;

FIG. 5B is a circuit diagram of the LNA in the main path along highlighting the MUX embedded therein and the reused portions of the LNA for the LNA circuit of FIG. 2;

FIG. 6 is a mixed circuit and block diagram illustrating an exemplary aspect of the inverting path of the LNA circuit of FIG. 2 using a non-inverting common gate amplifier and an inverting gain amplifier;

FIG. 7 is the mixed circuit and block diagram of FIG. 6 with additional details highlighting possible current reuse between the inverting path and the main path;

FIG. 8 is the mixed circuit and block diagram of FIG. 6 with an n-type field effect transistor in the inverting gain amplifier that cannot reuse current;

FIG. 9 is a block diagram illustrating an inverting path with feedback resistance for a common source impedance amplifier;

FIG. 10 is a flowchart illustrating an exemplary process for using an LNA according to aspects of the present disclosure; and FIG. 11 is a block diagram of a wireless communication device, which may include the LNAs of FIGS. 2-9 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled”to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include a noise-canceling low noise amplifier (LNA). In particular, a low noise amplifier path may include a plurality of inputs that are split into a main path (having a main LNA) and an inverting path. A multiplexer (MUX) in the inverting path generates switch noise which passes into both the switch path and the main path. The switch noise is inverted in the inverting path and also amplified. The switch noise is also amplified in the main path by the LNA. The inverted amplified switch noise and the amplified switch noise are then destructively summed to reduce or remove the switch noise at an output. The inverting path uses an active element in the form of an amplifier, which allows for substantial consolidation of matching circuits, thereby reducing the size of the LNA path. Additionally, some portions of the LNA may be shared, further reducing the size of the LNA path.

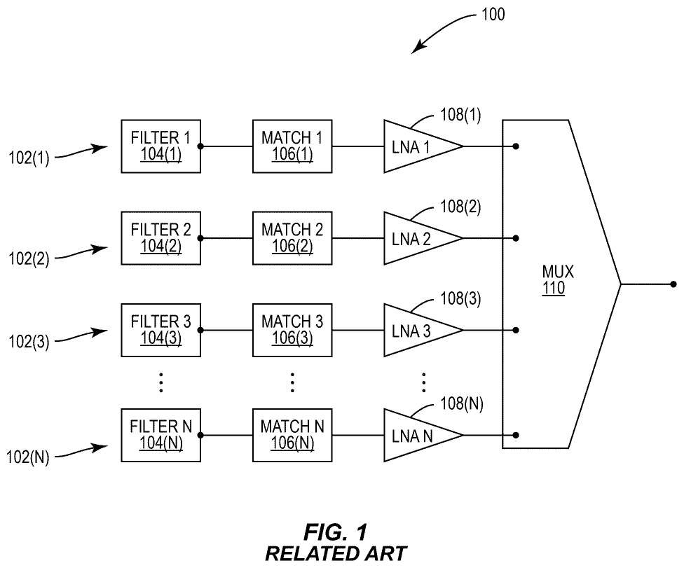

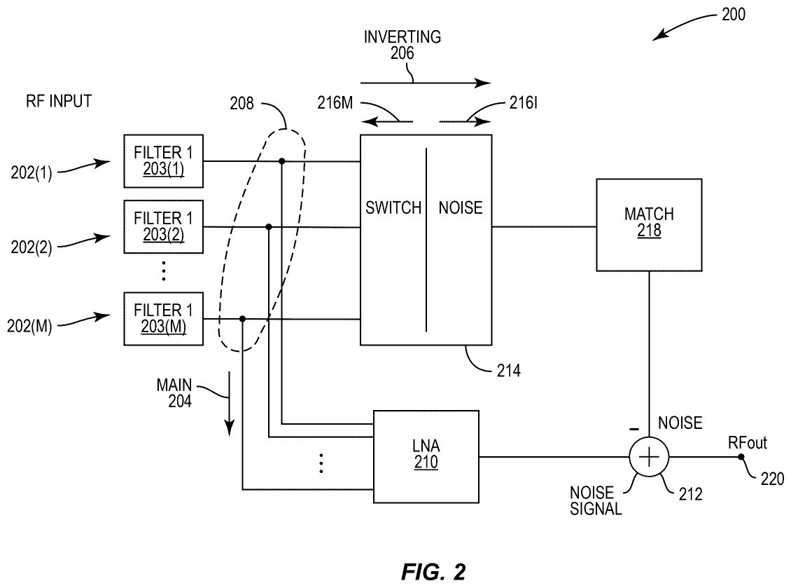

Before addressing aspects of the present disclosure, a brief overview of a conventional LNA path is provided with reference to FIG. 1. A discussion of aspects of the present disclosure begins below with reference to FIG. 2.

In operation, modern communication devices send and receive wireless signals. To receive a desired signal, a wireless device must be able to detect signals in any of these multiple frequency bands, amplify the signal to an acceptable level, and then process the signal for use. This reception is done, in large part, in a front-end module (FEM) that couples to an antenna or antenna array, filters the incoming signal, performs some impedance matching, and then amplifies the signal with an LNA. This amplified signal is then processed (e.g., downconverted to a baseband, decoded, and the like, as better explained below with reference to FIG. 11).

As the various wireless standards have evolved, signals are sent and received across multiple frequency bands. These multiple frequency bands necessitate front-end modules that have plural receive paths for the multiple bands that are supported. The brute force approach to providing these multiple receive paths is illustrated in FIG. 1.

In this regard, FIG. 1 illustrates an LNA circuit 100 with a plurality of receive paths 102(1)-102(N), where each receive path 102(1)-102(N) has a respective filter 104(1)-104(N), a respective matching circuit 106(1)-106(N), and a respective LNA 108(1)-108(N). The matching circuits 106(1)-106(N) are typically individual inductors. The LNAs 108(1)-108(N) are typically narrow-band LNAs. A MUX 110 selects a desired receive path from amongst the receive paths 102(1)-102(N). The placement of the MUX 110 after the LNAs 108(1)-108(N) means that the MUX 110 does not contribute substantially to the noise factor of the LNA circuit 100. However, the presence of N filters 104(1)-104(N), inductors for the matching circuits 106(1)-106(N), and LNAs 108(1)-108(N) consumes relatively large amounts of space. Space is increasingly a premium in wireless communication devices, particularly mobile devices. Accordingly, there is room for improvement in the LNA circuit that preserves a desired noise factor and reduces the overall footprint of the LNA circuit.

Aspects of the present disclosure contemplate sharing portions of the receive paths to consolidate space use. To preserve the desired noise factor, the received signal is split into two paths - specifically, a main path and an inverting path. Noise generated in the MUX is inverted in the inverting path and then destructively summed with the noise in the main path to provide noise cancelation. A number of variations on how to implement this exist and are explored below, but a discussion of the basic structure begins with reference to FIG. 2.

In this regard, FIG. 2 illustrates an LNA circuit 200 with a plurality of receive paths 202(1)-202(M) at a radio frequency (RF) input. Each receive path 202(1)-202(M) has a respective input node (not shown) that couples to a respective filter 203(1)-203(M) and splits then into a main path 204 and an inverting path 206 generally at 208 (essentially after the filters 203(1)-203(M)).

In the main path 204, a main LNA 210 also acts as a MUX and provides an amplified signal from a selected receive path from amongst the plurality of receive paths 202(1)-202(M) to a summation node 212.

In the inverting path 206, a switch circuit 214 acts as a MUX. More details on the switches are provided below. These switches generate noise, which travels both into the main path 204 (shown generally at 216M) and also into the inverting path 206 (shown generally at 216I). An active impedance matching circuit 218 acts as a consolidated impedance matching circuitry (analogous to the matching circuits 106(1)-106(N) and also inverts the signal from the switch circuit 214. The amplified signal is provided to the summation node 212.

More specifically, the noise from the switch circuit 214 is amplified by the main LNA 210. The noise from the switch circuit 214 is also amplified, but inverted, by the active impedance matching circuit 218 such that when the signals are summed at the summation node 212, the noise along the main path 204 and the noise along the inverting path 206 destructively sums to reduce or possibly even eliminate the noise. This removal of the noise provides a desirable noise factor for the LNA circuit 200. The remaining amplified signal is then output at an output node 220.

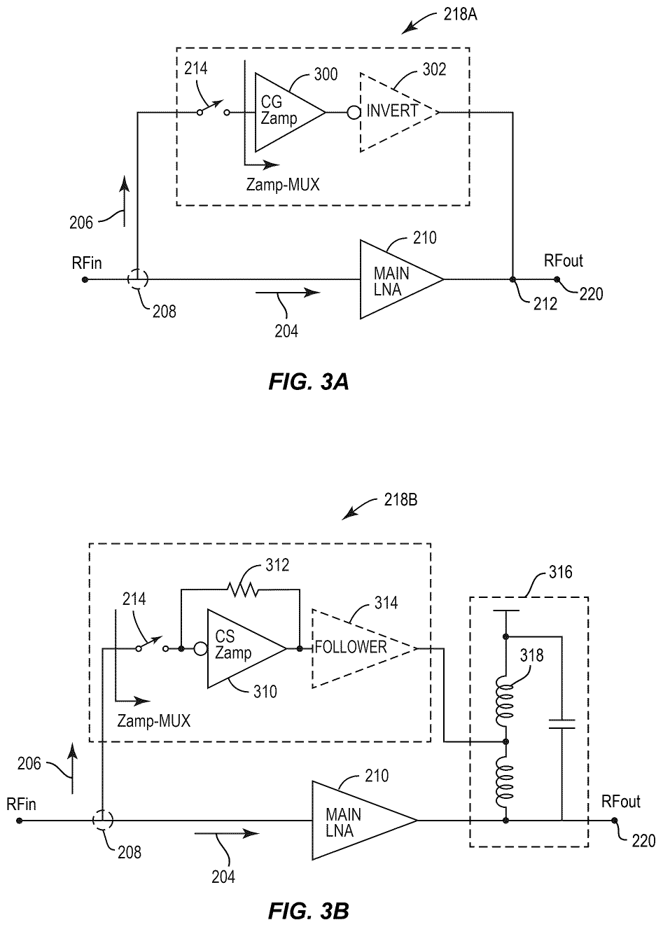

FIGS. 3A & 3B provide additional details about possible variants of the impedance matching circuit 218. While the main LNA 210 and the main path 204 are illustrated in both Figures, the details are minimal as the focus is on the impedance matching circuits 218A and 218B, respectively.

In this regard, FIG. 3A illustrates the impedance matching circuit 218A with a common gate impedance matching amplifier 300 (also referred to as Zamp). The impedance matching amplifier 300 is a non-inverting stage, and accordingly, there is an inverting stage 302, which may also be an amplifier. By providing an active element for impedance matching (i.e., the amplifier 300), the need for duplicative inductors (and the corresponding space penalty) is reduced.

Similarly, FIG. 3B illustrates the impedance matching circuit 218B with a common source impedance matching amplifier 310 (again sometimes referred to as Zamp). The impedance matching amplifier 310 is an inverting stage and also has a feedback resistor 312. Note that the location of the feedback resistor 312 means that noise from the resistor 312 is not shared on both paths 204, 206. Optionally, a follower amplifier 314 may be provided in the inverting path 206. Summation node 212 may be modified by an output LC-tank 316 (having an inductor 318 and a capacitor (unlabeled)) that uses a tap on the inductor 318 to ensure different gains for the different paths 204, 206 to help offset the noise from the feedback resistor 312.

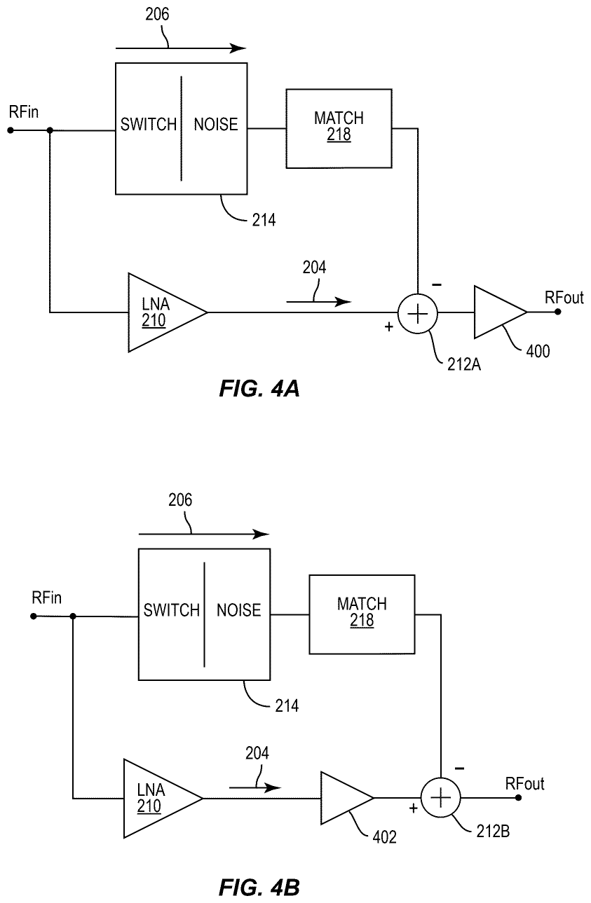

FIGS. 4A & 4B provide additional details about the summation node 212 and, more specifically, the location of the summation node 212. In particular, the main path 204 may have just the main LNA 210, as shown in FIG. 4A, and a cascode amplifier 400 be provided downstream of the summation node 212A. Alternatively, a cascode amplifier 402 may be positioned between the main LNA 210 and the summation node 212B as shown in FIG. 4B.

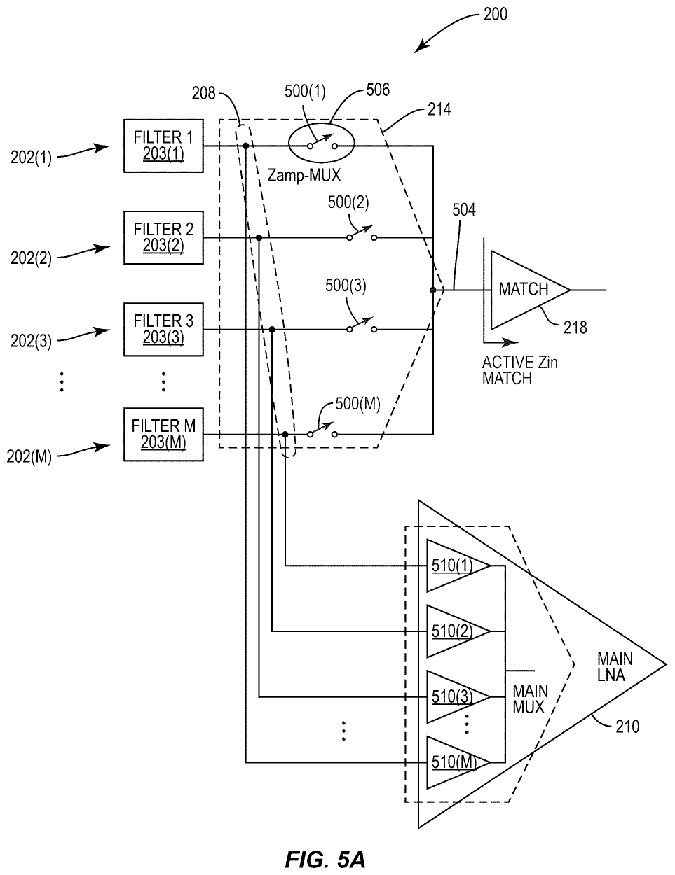

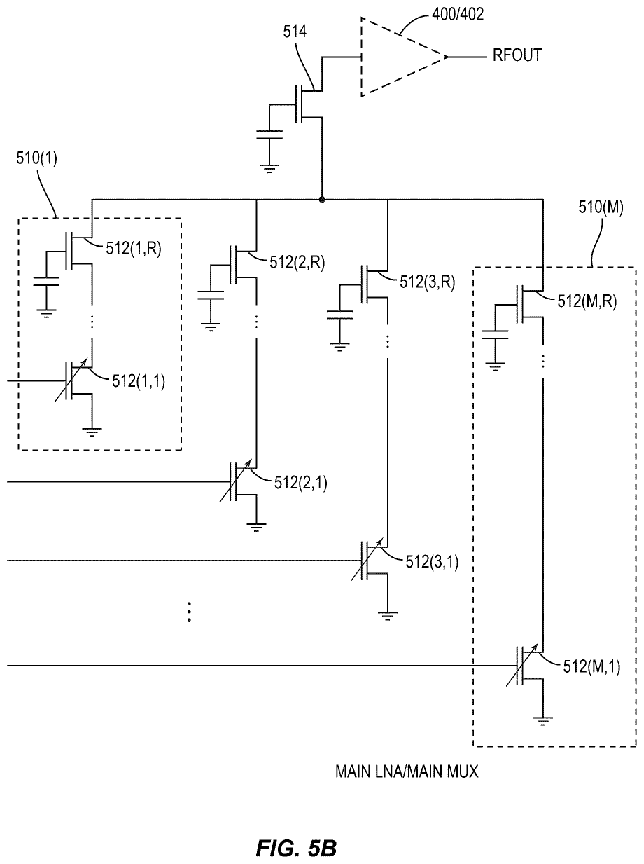

FIGS. 5A & 5B provide additional details about the switches in the inverting path 206 and the main path 204, respectively. More specifically, FIG. 5A shows details about the switch circuit 214. The switch circuit 214 includes M switches 500(1)-500(M) corresponding to the M receive paths 202(1)-202(M). Collectively, the switches 500(1)-500(M) effectively MUX the paths to a single path 504. However, the switches act as a noise source (shown by circle 506) (as also explained above with reference to FIG. 2). The impedance matching circuit 218 is, as noted, an active impedance circuit, which with the filers 203(1)-203(M), provides a desired impedance for the selected receive path 202(1)-202(M) (202(1) selected in FIG. 5A).

FIG. 5A also shows that the main LNA 210 is also formed from a plurality of narrow-band LNAs 510(1)-510(M). As better shown in FIG. 5B, the narrow band LNAs 510(1)-510(M) may be formed from cascoded transistors 512(1, 1)-512(M, R). The transistors 512(1, 1)-512(M, 1) act as switches to select which path is active and passed to a shared cascode transistor 514.

Thus, while there are distinct filters 203(1)-203(M) and some distinct portions of the LNAs 510(1)-510(M), the overall LNA circuit 200 shares the active impedance matching circuit 218. Sharing the impedance allows the elimination of many inductors (by far, the largest element in the traditional circuit 100) and provides the desired space savings. Likewise, the shared cascode transistor 514 may be relatively large compared to the cascoded transistors 512(1, 1)-512(M, R), and thus, there may be some space savings over the individual LNAs 108(1)-108(N).

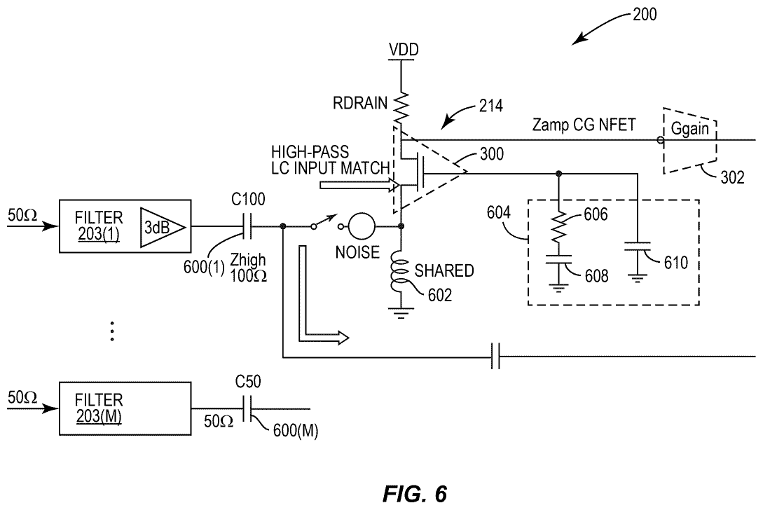

FIGS. 6-9 illustrate additional details about the impedance matching circuit 218. Specifically, it can be seen that the filters 203(1)-203(M) may have different impedances and be associated with respective capacitors 600(1)-600(M) (which may have different values). The common gate impedance matching amplifier 300 may use a degenerative inductor 602. While this one inductor 602 may consume space, the space consumed is much less than having an inductor in each receive path 202(1)-202(M). The inverting stage 302 may be an n-type or p-type field effect transistor (NFET or PFET). Additional bias circuit 604 may be a bias resistor 606 and capacitors 608, 610.

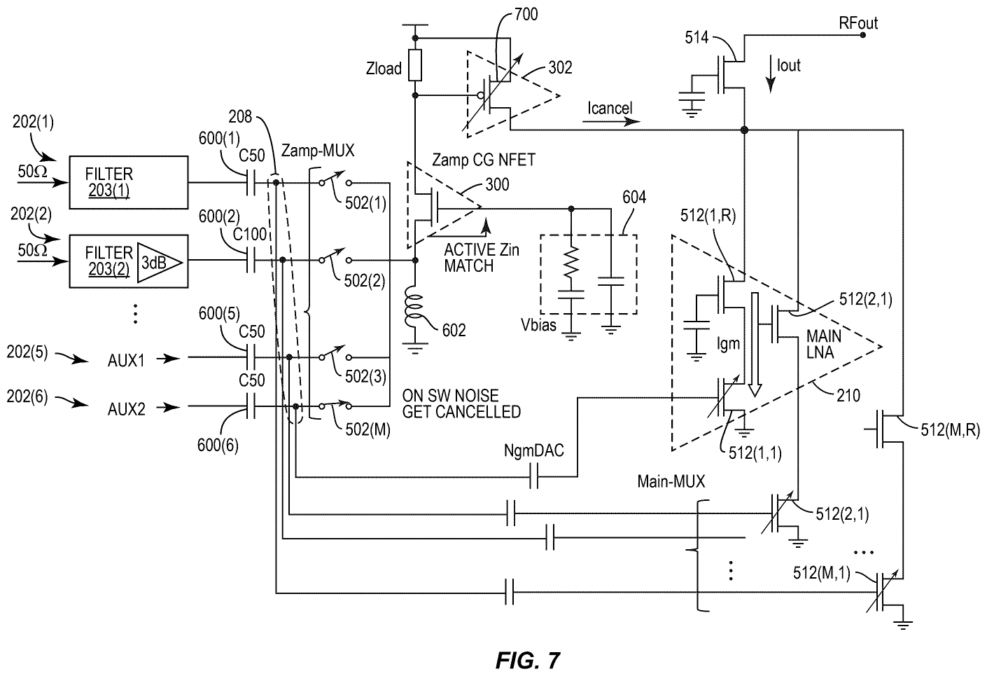

FIG. 7 illustrates that not every receive path 202(1)-202(M) will include a respective filter 203(1)-203(M) (e.g., receive paths 202(5), 202(6)). However, capacitors 600(1)-600(M) are still present (including capacitors 600(5), 600(6)). As illustrated, the inverting stage 302 is a PFET, and the transistors in the main LNA 210 are NFETs. This allows current reuse between the PFET 700 and the transistors 512(1, R)-512(M, R).

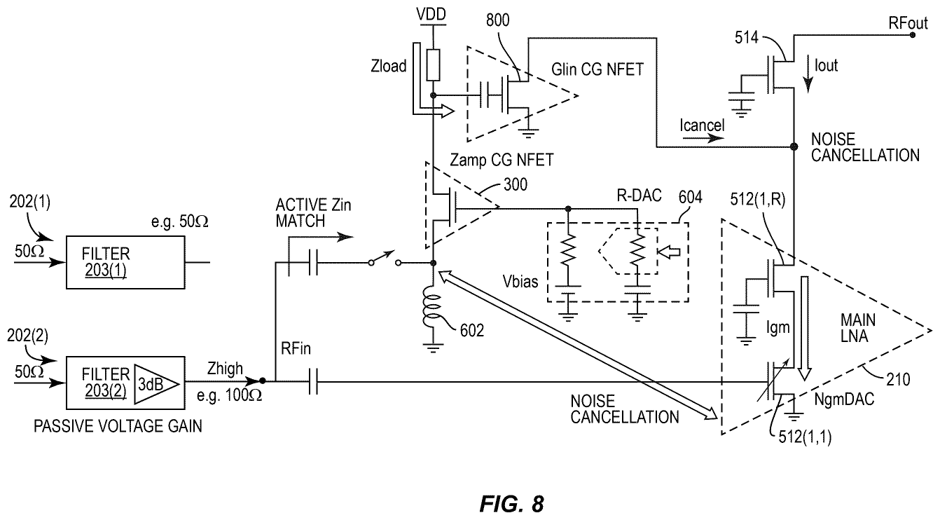

FIG. 8 is similar to FIG. 7, but instead of PFET 700, an NFET 800 is used in the inverting stage 302. The use of the NFET prevents current reuse but may allow for easier manufacturing in some cases.

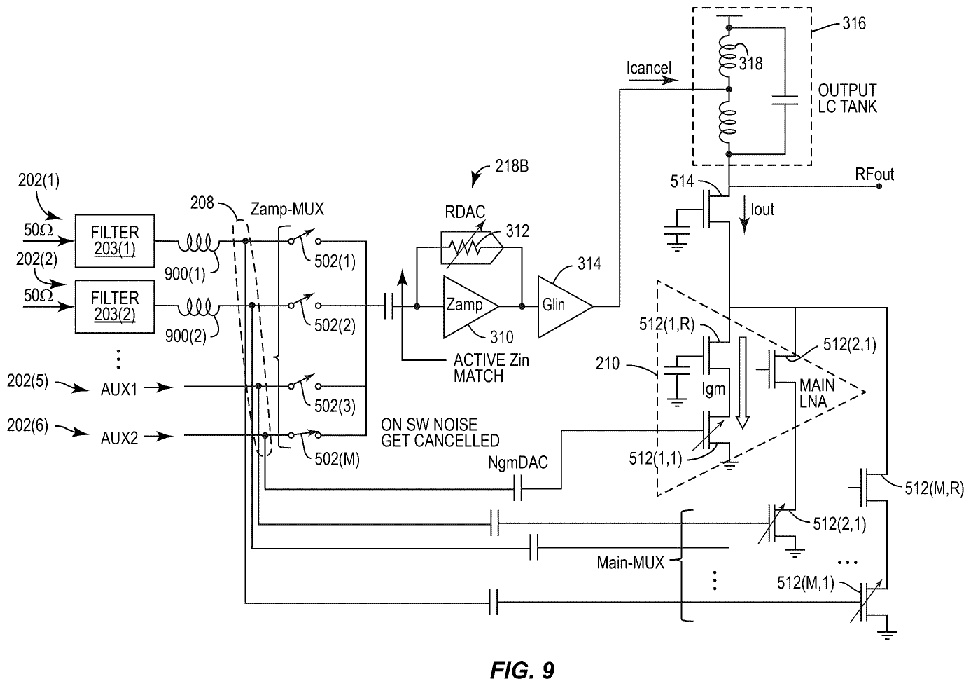

FIG. 9 shows additional details about the aspect introduced in FIG. 3B, namely, where a common source inverting impedance matching circuit 218B is used. In contrast to FIGS. 6 and 7, which use capacitors 600(1)-600(M), the common source Zamp may use inductor 900(1)-900(M′) (although some receive paths may omit the inductor so as illustrated, M′=2).

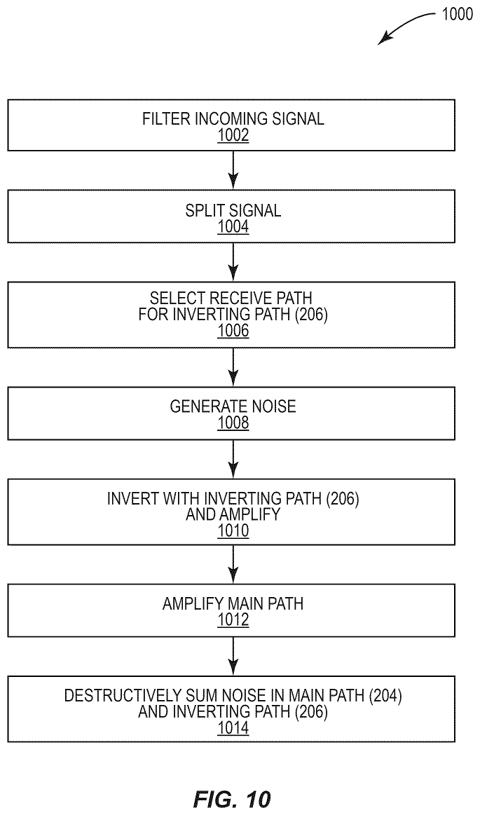

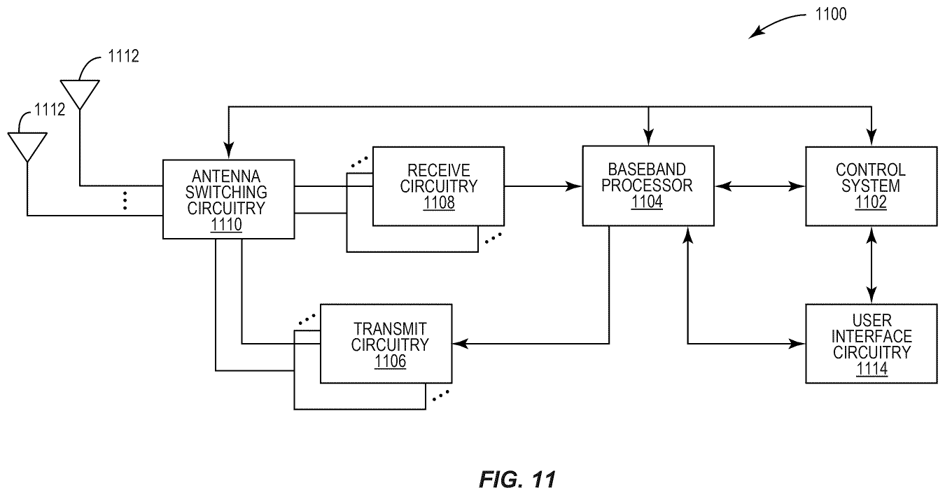

FIG. 10 is a flowchart of a process 1000 for using the LNA circuit 200 of the present disclosure. The process 1000 begins with an optional step of filtering incoming signals (block 1002) with a filter 203(1)-203(M), with the understanding that some signals, such as those from an auxiliary port, may not need to be filtered.

The signal is then split (block 1004) at 208. The switch circuit 214 selects a receive path for the inverting path 206 (block 1006). The switch in the switch circuit 214 will generate noise (block 1008) that goes into the inverting path 206 and the main path 204. The signal on the inverting path 206 is inverted and amplified (block 1010). The signal (including noise from the switch circuit 214) on the main path 204 is amplified (block 1012). The noise from the main path 204 and the inverting path 206 is then destructively summed (block 1014), and an output signal is provided for further processing.

The noise canceling LNA, according to aspects disclosed herein, may be provided in or integrated into a receiver in any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

Further, while cellular wireless signals are specifically contemplated, the disclosure is not so limited, and BLUETOOTH, WIFI, or the like may also benefit from the present disclosure.

Still further, while certain types of transistors are shown, it should be appreciated that various technologies (complementary metal oxide semiconductor (CMOS), bulk-CMOS, silicon on insulator (SOI) CMOS, JFET, or bipolar CMOS processes may be used without departing from the present disclosure.

FIG. 11 is a schematic diagram of an exemplary communication device 1100 wherein the LNA circuit 200 can be provided. Herein, the communication device 1100 can be any type of communication device, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 1100 will generally include a control system 1102, a baseband processor 1104, transmit circuitry 1106, receive circuitry 1108, antenna switching circuitry 1110, multiple antennas 1112, and user interface circuitry 1114. In a non-limiting example, the control system 1102 can be a field-programmable gate array (FPGA) or an application-specific integrated circuit (ASIC), as an example. In this regard, the control system 1102 can include at least a microprocessor(s), an embedded memory circuit(s), and a communication bus interface(s). The receive circuitry 1108 receives radio frequency signals via the antennas 1112 and through the antenna switching circuitry 1110 from one or more base stations. A low noise amplifier and a filter of the receive circuitry 1108 (such as those of the present disclosure) cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1104 processes the digitized received signal to extract the information or data bits conveyed in the received signal. This processing typically comprises demodulation, decoding, and error correction operations. The baseband processor 1104 is generally implemented in one or more digital signal processors (DSPs) and ASICs.

For transmission, the baseband processor 1104 receives digitized data, which may represent voice, data, or control information, from the control system 1102, which it encodes for transmission. The encoded data is output to the transmit circuitry 1106, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1112 through the antenna switching circuitry 1110. The multiple antennas 1112 and the replicated transmit and receive circuitries 1106, 1108 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A low noise amplifier (LNA) circuit comprising:
a plurality of receive paths, each comprising a respective input node, wherein each receive path splits into a main path and an inverting path;
a switching circuit comprising a plurality of switches, each of the plurality of switches coupled to a respective receive path among the plurality of receive paths, the switching circuit configured to:
couple one of the respective input nodes to the inverting path; and
introduce noise to the inverting path and the main path;
wherein the main path comprises an LNA configured to amplify the noise introduced by the switching circuit;
wherein the inverting path comprises:
an impedance matching circuit; and
an inverting amplifier configured to amplify the noise introduced by the switching circuit; and
a summation node configured to sum destructively the noise in the main path and the inverting path.

2. The LNA circuit of claim 1, wherein the impedance matching circuit comprises a common gate amplifier.

3. The LNA circuit of claim 2, wherein the impedance matching circuit further comprises a degenerative inductor coupled to the common gate amplifier.

4. The LNA circuit of claim 2, wherein the inverting amplifier is serially positioned after the common gate amplifier.

5. The LNA circuit of claim 1, wherein the inverting amplifier comprises a common source amplifier and a feedback resistor.

6. The LNA circuit of claim 1, further comprising at least one filter positioned serially between the switching circuit and at least one input node.

7. The LNA circuit of claim 6, further comprising a capacitor positioned between the at least one filter and the switching circuit.

8. The LNA circuit of claim 1, further comprising a cascoded amplifier positioned serially after the LNA.

9. The LNA circuit of claim 8, wherein the summation node is positioned between the cascoded amplifier and the LNA.

10. The LNA circuit of claim 8, wherein the summation node is positioned between the cascoded amplifier and an output.

11. The LNA of claim 1, wherein the LNA comprises a plurality of transistors, wherein at least one of the transistors is configured to act as a switch to couple one of the input nodes to at least one other of the plurality of transistors.

12. A wireless communication device comprising:
a baseband processor (BBP);
a transceiver coupled to the BBP, the transceiver comprising a receiver, the receiver comprising a low noise amplifier (LNA) circuit comprising:
a plurality of receive paths, each comprising a respective input node, wherein each receive path splits into a main path and an inverting path;
a switching circuit comprising a plurality of switches, each of the plurality of switches coupled to a respective input node, the switching circuit configured to:
couple one of the respective input nodes to the inverting path; and
introduce noise to the inverting path and the main path;
wherein the main path comprises an LNA configured to amplify the noise introduced by the switching circuit;
wherein the inverting path comprises:
an impedance matching circuit; and
an inverting amplifier configured to amplify the noise introduced by the switching circuit; and
a summation node configured to sum destructively the noise in the main path and the inverting path.

13. The wireless communication device of claim 12, wherein the impedance matching circuit comprises a common gate amplifier.

14. The wireless communication device of claim 13, wherein the impedance matching circuit further comprises a degenerative inductor coupled to the common gate amplifier.

15. The wireless communication device of claim 13, wherein the inverting amplifier is serially positioned after the common gate amplifier.

16. The wireless communication device of claim 12, wherein the inverting amplifier comprises a common source amplifier and a feedback resistor.

17. The wireless communication device of claim 12, further comprising at least one filter positioned serially between the switching circuit and at least one input node.

18. The wireless communication device of claim 12, wherein the receiver is configured to operate in at least one protocol, selected the group consisting of: BLUETOOTH, WiFi, and cellular.

19. A method of canceling noise at a receiver, the method comprising:
splitting a received signal onto a main path and an inverting path;
introducing noise on the main path and the inverting path with a switch in the inverting path;
using an active impedance matching amplifier in the inverting path to match impedance and amplify noise from the switch;
amplifying the noise on the main path with a low noise amplifier (LNA); and
destructively summing noise from the inverting path and the main path.

20. The method of claim 19, wherein using the active impedance matching amplifier comprises inverting the noise with the active impedance matching amplifier.
